(19) United States
(12) Patent Application Publication
(10) Pub. No.: US 2012/0081495 A1
(43) Pub. Date: Apr. 5, 2012

(54) ORGANIC EL DEVICE, LIGHT SOURCE MODULE AND PRINTER

(75) Inventors: Hirofumi Kubota, Maikata-Shi (JP); Satoshi Okutani, Ishikawa-Ken (JP); Masuyuki Oota, Hakusan-Shi (JP)

(73) Assignee: Toshiba Mobile Display Co., Ltd., Saitama-ken (JP)

(21) Appl. No.: 13/149,830

(22) Filed: May 31, 2011

(30) Foreign Application Priority Data
Oct. 1, 2010 (JP) JP2010-224112

(51) Int. Cl. B41J 2/435; H01L 33/08; H01L 33/58

(52) U.S. Cl. 347/224; 257/88; 257/98; 257/E33.005; 257/E33.073

(57) ABSTRACT

According to one embodiment, an organic EL device includes a substrate, a first translucent insulating film, a second translucent insulating film, a first electrode, a second electrode, and an emitting layer. The substrate has a first index of refraction. The first translucent insulating film is on the substrate, and the first insulating film has a second index of refraction higher than the first index of refraction. The second translucent insulating film is on the first insulating film, and the second insulating film has a third index of refraction lower than the second index of refraction. The first electrode is on the second insulating film, and the first electrode has a fourth index of refraction higher than the third index of refraction. The second electrode is facing the first electrode. The emitting layer is between the first electrode and the second electrode.

### CROSS REFERENCE TO RELATED APPLICATIONS

This application is based upon and claims the benefit of priority from the prior Japanese Patent Application No. 2010-224112, filed on Oct. 1, 2010, the entire contents of which are incorporated herein by reference.

### FIELD

Embodiments described herein relate generally to an organic EL device, a light source module and a printer.

### BACKGROUND

In order to perform high-speed printing using a printer where an organic EL (electroluminescence) device is used as a printer head, it is necessary to shorten a exposure time of a photosensitive drum by improving an emission luminance of the organic EL device. If a large current is applied on the organic EL device for improving luminance, the device may be heated, which can cause problems that the lifetime of the device may be shortened or the device may be broken.

### BRIEF DESCRIPTION OF THE DRAWINGS

FIG. 1 is a schematic block diagram showing a printing system using an organic EL device 2 according to a first embodiment.

FIG. 2 is a cross section of the organic EL device 2.

FIG. 3 is a more detailed cross section of the pixel 7.

FIGS. 4A and 4B are graphs where an emitting efficiency with the first and the second insulating films IL1 and IL2 is compared to that without the first and the second insulating films IL1 and IL2 by a simulation.

FIG. 5 is a top view of the organic EL device 2.

### DETAILED DESCRIPTION

In general, according to one embodiment, an organic EL device includes a substrate, a first translucent insulating film, a second translucent insulating film, a first electrode, a second electrode, and an emitting layer. The substrate has a first index of refraction. The first translucent insulating film is on the substrate, and the first insulating film has a second index of refraction higher than the first index of refraction. The second translucent insulating film is on the first insulating film, and the second insulating film has a third index of refraction lower than the second index of refraction. The first electrode is on the second insulating film, and the first electrode has a fourth index of refraction higher than the third index of refraction. The second electrode is facing the first electrode. The emitting layer is between the first electrode and the second electrode.

Embodiments will now be explained with reference to the accompanying drawings.

### First Embodiment

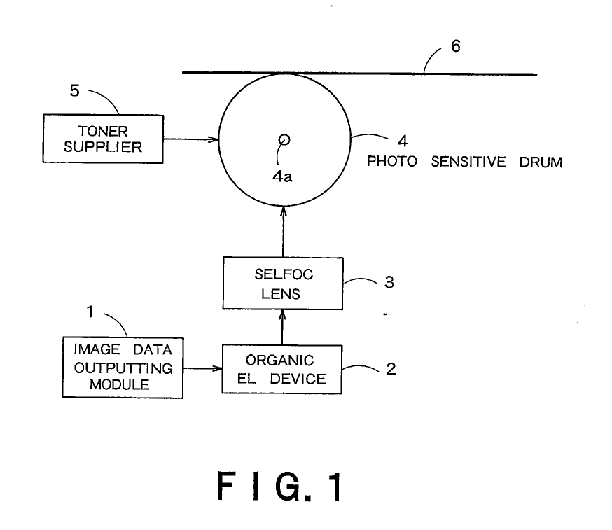

FIG. 1 is a schematic block diagram showing a printing system using an organic EL device 2 according to a first embodiment. The printing system has an image data outputting module 1, a light source module having the organic EL device 2 and a Selfoc lens 3, a photosensitive drum 4 and a toner supplier 5. The printing system performs printing on a paper 6 as below.

Firstly, the entire surface of the photosensitive drum 4 is uniformly charged. Then, the organic EL device 2 emits light whose pattern depends on an image data (including characters) outputted from the image data outputting module 1. This light is collected by the Selfoc lens 3 and forms an image on the photosensitive drum 4 which rotates around an axis 4a provided perpendicular to the drawing. The photosensitive drum 4 is exposed with a pattern depending on the image data, and exposed parts are discharged. Note that, the photosensitive property of the photosensitive drum 4 is adjusted so that the sensitivity becomes high at a wavelength of the light emitted by the organic EL device 2. Next, toners are supplied by the toner supplier 5 and attach only on the charged parts of the photosensitive drum 4. Then, the paper 6 is pressed on the photosensitive drum 4, and the image depending on the image data is printed on the paper 6 by transcribing the toners attaching on the photosensitive drum 4 into the paper 6.

The first embodiment is intended to improve printing speed by irradiating a high-luminance light to the photosensitive drum 4 from the organic EL device 2 to expose the photosensitive drum 4 promptly.

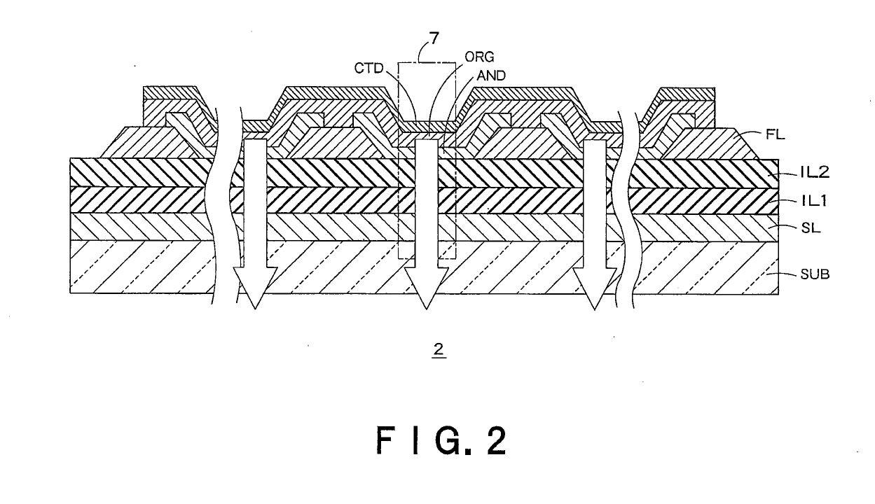

FIG. 2 is a cross section of the organic EL device 2. The organic EL device 2 has a substrate SUB, a signal line SL, a first insulating film IL1, a second insulating film IL2, an anode AND, an organic layer ORG, a cathode CTD, and a flatting layer FL. The anode AND is provided for each of pixels 7. The flatting layer FL is formed in rib-shape to separate the pixels 7 from each other. The other layers are common to all of the pixels 7. Note that, it is not always necessary to form the flatting layer FL.

The organic EL device 2 of FIG. 2 is a bottom-surface emitting type organic EL device where light emitted by the organic layer ORG is taken out from a bottom surface (the substrate SUB). As shown in FIG. 2, the flatting layer FL is not formed under the organic layer ORG.

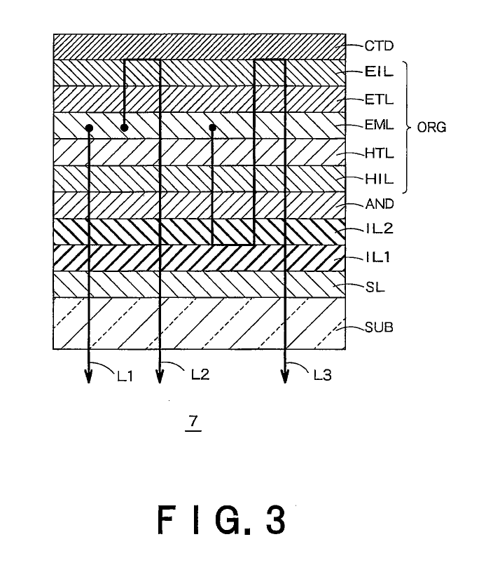

FIG. 3 is a more detailed cross section of the pixel 7. The organic layer ORG has a hole injection layer HIL, a hole transport layer (carrier transfer layer) HTL, an emitting layer EML, an electron transport layer ETL, and an electron injection layer EIL. The emitting layer EML emits light whose color depends on the impurities in the emitting layer EML when holes injected from the anode AND through the holes injection layer HIL and the hole transport layer HTL and electrons injected from the cathode. CTD through the electron injection layer EIL and the electron transport layer ETL recombine. Note that, it is enough that the organic layer ORG has at least the emitting layer EML, and the electron injection layer EIL and so on can be arbitrarily provided if needed.

The substrate SUB is made of a glass, for example. The signal line SL is formed on the substrate SUB. The first insulating film IL1 formed on the signal line SL is made of SiN (silicon nitride) having a thickness of 320 nm, for example. The second insulating film IL2 formed on the first insulating film IL1 is made of SiO₂ (silicon dioxide) having a thickness of 370 nm. The first and the second insulating films IL1 and IL2 also act as interlayer insulating film between the signal line SL and the anode AND.

The anode AND is made of a transmissive material such as ITO (Indium Tin Oxide) and formed by a sputter manner, for example. When the organic EL device 2 is used for the printer head, the color of the light emitted by the emitting layer EML can be monochromatic, and can be red in accordance with an exposure wavelength of the photosensitive drum 4. The organic layer ORG is formed by a vapor-deposition manner, for example. The cathode CTD is made of a non-transmissive material such as Al (Aluminum) and formed by a metal vapor-deposition manner, for example.

Here, the first and the second insulating films IL1 and IL2 are made of translucent materials. Furthermore, when the materials of the substrate SUB, the first insulating film IL1, the second insulating film IL2 and the anode AND are glass, SiN, SiO₂ and ITO, respectively, indexes of refraction thereof are 1.5, 3, 1.5, 2, respectively. That is, the index of refraction of the first insulating film IL1 is higher than that of the substrate SUB, that of the insulating film IL2 is lower than that of the first insulating film IL1, and that of the anode AND is higher than that of the second insulating film IL2.

Therefore, first light L1, second light L2 and third light L3 of FIG. 3 resonate. Here, the first light L1 is light emitted by the emitting layer EML toward the substrate SUB transmissive through the first and the second insulating films IL1 and IL2 without reflected thereon, the second light L2 is light emitted toward the cathode CTD and reflected thereon toward the substrate SUB, and the third light is light emitted toward the substrate SUB and reflected on the interface between the first and the second insulating films IL1 and IIL2 and further reflected on the cathode CTD toward the substrate SUB. As a result, the first to the third light are strengthened by each other, and the luminance of the light taken out from the substrate SUB side improves.

It is enough for the organic EL device 2 for the printer head to emit monochromatic light and it is unnecessary to widen a view angle. Therefore, sufficiently high-luminance light can be obtained by a structure provided only the first and the second insulating films IL1 and IL2.

Note that, the materials of the first and the second insulating films IL1 and IL2 are not limited to the SIN and the SiO₂, respectively, and materials satisfying the above relation can be applicable. Furthermore, it is not always necessary that the first to the third lights L1 to L3 are strengthened, and when two of them are strengthened, it is possible to improve the luminance.

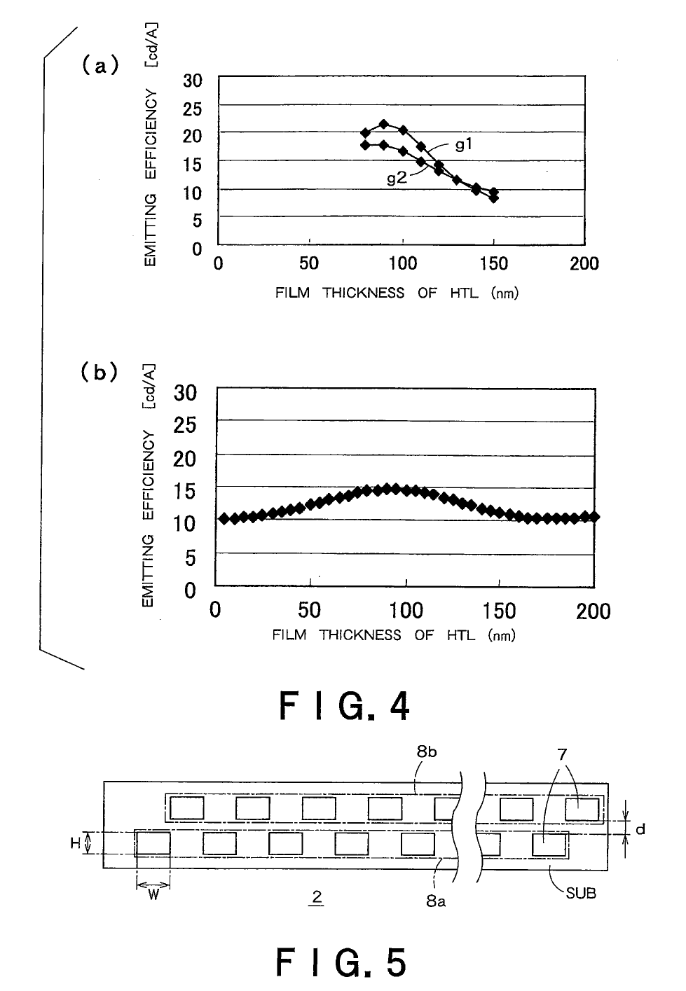

FIGS. 4A and 4B are graphs where an emitting efficiency with the first and the second insulating films IL1 and IL2 is compared to that without the first and the second insulating films IL1 and IL2 by a simulation. A curve g1 of FIG. 4A shows an emitting efficiency where the first insulating film IL1 is made of the SiN having a thickness of 320 nm and the second insulating film IL2 is made of the SiO₂ having a thickness of 370 nm. A curve g2 of FIG. 4A shows an emitting efficiency where the first insulating film IL1 is made of the SiN having a thickness of 350 nm and the second insulating film IL2 is made of the SiO₂ having a thickness of 340 nm. Further, the thickness of the hole transport layer HTL is varied both in curves g1 and g2 of FIG. 4A. On the other hand, in FIG. 4B, an emitting efficiency is shown where the first and the second insulating films IL1 and IL2 are not provided.

As shown in FIG. 4A, by adjusting the thicknesses of the first and the second insulating films and the hole transport layer HTL properly, the emitting efficiency can reach 21 cd/A at maximum. Contrarily, as shown in FIG. 4B, when the first and the second insulating films are not provided, the emitting efficiency is only 15 cd/A at maximum. Thus, by providing the first and the second insulating films IL1 and IL2, the emitting efficiency improves by a factor of about “1.4” times.

As stated above, in the first embodiment, the first and the second insulating films IL1 and IL2 whose indexes of refraction satisfy a predetermined relation are provided. Therefore, the first to the third light L1 to L3 are strengthened, thereby improving the emission luminance without applying large current. As a result, the printing speed improves.

If an aluminum film is provided instead of the first and the second insulating films IL1 and IL2, the emission luminance may decrease because the transmission factor of the aluminum is not high enough. If silver film is provided, a costly apparatus for forming silver film is needed. On the other hand, in the first embodiment, the translucent first and the second insulating films IL1 and IL2 made of the SiO₂, SiN and so on are used, thereby improving the emission luminance while suppressing the cost.

### Second Embodiment

A second embodiment, which will be explained below, is intended to scale-down the pixel 7 applying the first embodiment which can improve the emission luminance.

FIG. 5 is a top view of the organic EL device 2. Hereinafter, a numeral example will be shown where printing is performed on an A4 paper 6. Furthermore, explanations common to the first embodiment will be omitted and differences therefrom will be mainly described.

As shown in FIG. 5, the shape of the substrate SUB is a rectangle. Here, the longer side direction of the substrate SUB is defined as horizontal direction, and the shorter side direction thereof is defined as vertical direction. On the substrate SUB, a plurality of emitting modules, which are separated from each other in the vertical direction, are arranged. The emitting module has a plurality of pixels 7 formed along the horizontal direction. In a example of FIG. 5, a first emitting module 8a where “720” pixels 7 are arranged in the horizontal direction in line, and a second emitting module 8b where the same number of pixels 7 are also arranged in the horizontal direction in another line, the first and the second emitting module being separated from each other by a distance “d” in hound's tooth check shape. The horizontal direction length W of the pixel 7 is determined depending on the width of the paper 6 and so on, and is, for example, 80 μm. In the second embodiment, the vertical length H of the pixels 7 is shorter than the horizontal length W, and is, for example, 40 μm. When the organic EL device 2 is used in the printing system of FIG. 1, the organic EL device 2 is arranged so that the longer side direction of the substrate SUB is parallel to the axis 4a of the photosensitive drum 4, in the other words, the longer side direction thereof is perpendicular to the rotating direction of the photosensitive drum 4.

Because the vertical length H is shorter, the distance “d” can be set large without scaling-up the substrate SUB in the vertical direction, and for example, the vertical length of the substrate SUB can be 30 μm. Therefore, it is possible to suppress that the printing patterns overlap in the vertical direction, thereby improving the printing resolution.

As described in the first embodiment, because the translucent first and the second insulating films IL1 and IL2 whose indexes of refraction satisfy a predetermined relation are provided, the emission luminance improves. Therefore, it is possible to suppress for the emission luminance to decrease at a minimum caused by shorting the vertical length H to scaling-down the pixel 7.

Note that, the arrangement of the pixel 7 is not limited to FIG. 5. Although FIG. 5 shows an example where the pixels 7 are arranged in hound's tooth check shape, these can be arranged in matrix shape. Furthermore, only one emitting module or more than three emitting modules can be arranged. Furthermore, the shape of the pixel 7 can be not a rectangle but an ellipse. In this case, horizontal direction corresponds to the longer axis and the vertical direction corresponds to the shorter axis. As the vertical direction length H is shorter, the printing speed improves. However, if the vertical direction length H is too short, it is difficult to deposit the organic layer ORG. Therefore, when the shape of the pixel 7 is a rectangle, it is preferable that the length of the vertical direction length H is equal to or longer than that of “⅕” of the horizontal direction length W, and when the shape of the pixel 7 is ellipse, it is preferable that the length of the shorter axis is equal to or longer than one-fifth of the length of the longer axis.

As stated above, in the second embodiment, the vertical direction length H of the pixel 7 is shorter than the horizontal direction length W. Therefore, it is possible to improve the printing resolution.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and spirit of the inventions.

1. An organic EL device comprising:
a substrate having a first index of refraction;
a first translucent insulating film on the substrate, the first insulating film having a second index of refraction higher than the first index of refraction;
a second translucent insulating film on the first insulating film, the second insulating film having a third index of refraction lower than the second index of refraction;
a first electrode on the second insulating film, the first electrode having a fourth index of refraction higher than the third index of refraction;
a second electrode facing the first electrode; and
an emitting layer between the first electrode and the second electrode.

2. The device of claim 1, wherein
the first insulating film is made of silicon nitride, and
the second insulating film is made of silicon dioxide.

3. The device of claim 1, wherein at least two of first light, second light and third light resonate,
the first light being light emitted by the emitting layer toward the substrate and transparent through the first insulating film and the second insulating film without reflecting thereon,
the second light being light emitted by the emitting layer toward the second electrode and reflected on the second electrode toward the substrate, and
the third light being light emitted by the emitting layer toward the substrate, reflected on an interface between the first insulating film and the second insulating film and further reflected at the second electrode toward the substrate.

4. The device of claim 3 further comprising a carrier transport layer between the first electrode and the emitting layer, the carrier transport layer transporting a carrier supplied from the first electrode to the emitting layer,
wherein a thickness of the carrier transport layer, a thickness of the first insulating film and a thickness of the second insulating film are set for at least two of the first light, the second light and the third light to resonate.

5. The device of claim 1, wherein a shape of the substrate is substantially a rectangle having a shorter side and a longer side, and
a length of the emitting layer in a direction of the shorter side is shorter than a length of the emitting layer in a direction of the longer side.

6. The device of claim 5, wherein the length of the emitting layer in the direction of the shorter side is equal to or longer than one-fifth of the length of the emitting layer in the direction of the longer side.

7. The device of claim 5, wherein a plurality of emitting modules are arranged on the substrate separated from each other in the direction of the shorter side,
each of the emitting modules comprising a plurality of emitting layers along the direction of the longer side.

8. An organic EL device comprising:
a substrate having a first index of refraction;
a first translucent insulating film on the substrate, the first insulating film having a second index of refraction higher than the first index of refraction;
a second translucent insulating film on the first insulating film, the second insulating film having a third index of refraction lower than the second index of refraction;
a first electrode on the second insulating film, the first electrode having a fourth index of refraction higher than the third index of refraction;
a second electrode facing the first electrode; and
an emitting layer between the first electrode and the second electrode,
wherein light emitted by the emitting layer is taken out from a side of the substrate.

9. The device of claim 8, wherein the second substrate is made of non-transmissive material.

10. The device of claim 8, wherein
the first insulating film is made of silicon nitride, and
the second insulating film is made of silicon dioxide.

11. The device of claim 8, wherein at least two of first light, second light and third light resonate,
the first light being light emitted by the emitting layer toward the substrate and transparent through the first insulating film and the second insulating film without reflecting thereon,
the second light being light emitted by the emitting layer toward the second electrode and reflected on the second electrode toward the substrate, and
the third light being light emitted by the emitting layer toward the substrate, reflected on an interface between the first insulating film and the second insulating film and further reflected at the second electrode toward the substrate.

12. The device of claim 11 further comprising a carrier transport layer between the first electrode and the emitting layer, the carrier transport layer transporting a carrier supplied from the first electrode to the emitting layer,
wherein a thickness of the carrier transport layer, a thickness of the first insulating film and a thickness of the second insulating film are set for at least two of the first light, the second light and the third light to resonate.

13. The device of claim 8, wherein a shape of the substrate is substantially a rectangle having a shorter side and a longer side, and
a length of the emitting layer in a direction of the shorter side is shorter than a length of the emitting layer in a direction of the longer side.

14. The device of claim 13, wherein the length of the emitting layer in the direction of the shorter side is equal to or longer than one-fifth of the length of the emitting layer in the direction of the longer side.

15. The device of claim 13, wherein a plurality of emitting modules are arranged on the substrate separated from each other in the direction of the shorter side,
each of the emitting modules comprising a plurality of emitting layers along the direction of the longer side.

16. A light source module comprising:
an organic EL device configured to emit light whose pattern depends on image data; and
a lens configured to collect the light emitted by the organic EL device,
wherein the organic EL device comprises:
a substrate having a first index of refraction;
a first translucent insulating film on the substrate, the first insulating film having a second index of refraction higher than the first index of refraction;
a second translucent insulating film on the first insulating film, the second insulating film having a third index of refraction lower than the second index of refraction;
a first electrode on the second insulating film, the first electrode having a fourth index of refraction higher than the third index of refraction;
a second electrode facing the first electrode; and
an emitting layer between the first electrode and the second electrode.

17. A printer comprising:
an organic EL device configured to emit light whose pattern depends on image data;
a lens configured to collect the light emitted by the organic EL device;
an image data outputting device configured to supply the organic EL device with the image data;
a photosensitive drum configured to be exposed by the light collected by the lens with the pattern depending on the image data; and
a toner supplier configured to supply the photosensitive drum with a toner with the pattern depending on the image data,
wherein the organic EL device comprises:
a substrate having a first index of refraction;
a first translucent insulating film on the substrate, the first insulating film having a second index of refraction higher than the first index of refraction;
a second translucent insulating film on the first insulating film, the second insulating film having a third index of refraction lower than the second index of refraction;
a first electrode on the second insulating film, the first electrode having a fourth index of refraction higher than the third index of refraction;
a second electrode facing the first electrode; and
an emitting layer between the first electrode and the second electrode.

18. The printer of claim 17, wherein the photosensitive drum has a photosensitive property in accordance with a wavelength of the light emitted by the emitting layer.

19. The printer of claim 17, wherein a shape of the substrate is substantially a rectangle having a shorter side and a longer side, and
a length of the emitting layer in a direction of the shorter side is shorter than a length of the emitting layer in a direction of the longer side.

20. The printer of claim 19, wherein the direction of the longer side is substantially perpendicular to a rotating direction of the photosensitive drum.
